(19) United States
(12) Patent Application Publication
(10) Pub. No.: US 2002/0004265 A1
(43) Pub. Date: Jan. 10, 2002

(54) Grind polish cluster and methods to remove visual grind pattern

(76) Inventors: Krishna Vepa, Livermore, CA (US); Duncan Dobson, Woodside, CA (US)

Correspondence Address: TOWNSEND AND TOWNSEND AND CREW, TWO EMBARCADERO CENTER, EIGHTH FLOOR, SAN FRANCISCO, CA, 94111-3834, US

(21) Appl. No.: 09/812,229

(22) Filed: Mar. 19, 2001

Related U.S. Application Data
(60) Provisional application No. 60/190,214, filed on Mar. 17, 2000.
(60) Provisional application No. 60/190,278, filed on Mar. 17, 2000.
(60) Provisional application No. 60/206,382, filed on May 23, 2000.

(51) Int. Cl. H01L 21/8238

(52) U.S. Cl. 438/200

(57) ABSTRACT

The present invention provides exemplary cluster tool systems and methods for processing wafers, including for grind polishing wafers to remove grind marks. In one embodiment, a substrate processing system includes a first platen (912) having a first platen surface adapted for mounting a substrate (920) thereto, and a second platen (910) having an annular ring (916) coupled thereto. The annular ring includes a grinding surface, and the first platen is offset from the second platen to position a portion of the annular ring proximate a center of the substrate. The system further includes a controller (950) coupled to the platens to facilitate operation thereof. In this manner, the substrate processing system is configured to use an abrasive grinding process for the removal of grind patterns previously disposed in the substrate surface.

### CROSS-REFERENCES TO RELATED APPLICATIONS

This application claims the benefit of the following U.S. patent applications, the complete disclosures of which are incorporated herein by reference:

Provisional Application No. 60/190,278 (Attorney Docket No. 20648-000100), filed on Mar. 17, 2000;

U.S. patent application Ser. No. ______ (Attorney Docket No. 20468-000110, entitled “Cluster Tool Systems and Methods for Processing Wafers,” filed on Mar. 15, 2001;

Provisional Application No. 60/190,214 (Attorney Docket No. 20468-000600), filed on Mar. 17, 2000; and

Provisional Application No. 60/206,382 (Attorney Docket No. 20468-001100), filed on May 23, 2000.

### BACKGROUND OF THE INVENTION

The present invention is directed to the processing of wafers, substrates or disks, such as silicon wafers, and more specifically to cluster tool systems and methods for processing wafers prior to device formation.

Wafers or substrates with exemplary characteristics must first be formed prior to the formation of circuit devices. In determining the quality of the semiconductor wafer, the flatness of the wafer is a critical parameter to customers since wafer flatness has a direct impact on the subsequent use and quality of semiconductor chips diced from the wafer. Hence, it is desirable to produce wafers having as near a planar surface as possible.

In a current practice, cylindrical boules of single-crystal silicon are formed, such as by Czochralski (CZ) growth process. The boules typically range from 100 to 300 millimeters in diameter. These boules are cut with an internal diameter (ID) saw or a wire saw into disc-shaped wafers approximately one millimeter (mm) thick. The wire saw reduces the kerf loss and permits many wafers to be cut simultaneously. However, the use of these saws results in undesirable waviness of the surfaces of the wafer. For example, the topography of the front surface of a wafer may vary by as much as 1-2 microns (μ) as a result of the natural distortions or warpage of the wafer as well as the variations in the thickness of the wafer across its surface. It is not unusual for the amplitude of the waves in each surface of a wafer to exceed fifteen (15) micrometers. The surfaces need to be made more planar (planarized) before they can be polished, coated or subjected to other processes.

FIG. 1 depicts a typical prior art method 10 for processing a silicon wafer prior to device formation. Method 10 includes a slice step 12 as previously described to remove a disc-shaped portion of wafer from the silicon boule. Once the wafer has been sliced, the wafer is cleaned and inspected (Step 14). Thereafter, an edge profile process (Step 16) is performed. Once the edge profile has been performed, the wafer is again cleaned and inspected (Step 18), and is laser marked (Step 20).

Next, a lapping process (Step 22) is performed to control thickness and remove bow and warp of the silicon wafer. The wafer is simultaneously lapped on both sides with an abrasive slurry in a lapping machine. The lapping process may involve one or more lapping steps with increasingly finer polishing grit. The wafer is then cleaned (Step 24) and etched (Step 26) to remove damage caused by the lapping process. The etching process may involve placing the wafer in an acid bath to remove the outer surface layer of the wafer. Typically, the etchant is a material requiring special handling and disposal. Thereafter, an additional cleaning of the wafer (Step 28) is performed.

The prior art method continues with a donor anneal (Step 30) followed by wafer inspection (Step 32). Thereafter, the wafer edge is polished (Step 24) and the wafer is again cleaned (Step 36). Typical wafer processing involves the parallel processing of a multitude of wafers. Hence at this juncture wafers may be sorted, such as by thickness (Step 38), after which a double side polish process is performed (Step 40).

The wafers then are cleaned (Step 42) and a final polish (Step 44) is performed. The wafers are again cleaned (Step 46), inspected (Step 48) and potentially cleaned and inspected again (Steps 50 and 52). For epitaxial substrates, a poly or oxide layer is overlaid to seal in the dopants after inspection Step 52. At this point, the wafer is packed (Step 54), shipped (Step 56) and delivered to the end user (Step 58). Hence, as seen in FIG. 1 and as described above, typical wafer processing involves a lengthy, time consuming process with a large number of processing steps.

A number of deficiencies exist with the prior art method. As can be seen from even a precursory review of FIG. 1, the prior art method requires a large number of steps to transform a wafer slice into a substrate suitable for creating circuit devices. The large number of process steps involved negatively effects production throughput, requires a large production area, and results in high fabrication costs. Additionally, each of the steps in FIG. 1 are typically performed at individual process stations. The stations are not grouped or clustered together, and manual delivery of the wafers between stations is often used.

In addition to the large number of process steps, at least some of the prior art steps themselves are slow or produce unacceptable results. For example, compared to a grinding process, the lapping process is slow and must be followed by careful cleaning and etching steps to relieve stresses before the wafer is polished. These additional steps cause the conventional method to be more expensive and time-consuming than methods of the present invention. Also, the etching process employed after the lapping step is undesirable from an environmental standpoint, because the large amount of strong acids used must be disposed of in an acceptable way.

In another prior art method, a grinding process replaces the lapping procedure in FIG. 1. A first surface of the wafer is drawn or pushed against a hard flat holder while the second surface of the wafer is ground flat. The forces used to hold the wafer elastically deform the wafer during grinding of the second surface. When the wafer is released, elastic restoring forces in the wafer cause it to resume its original shape, and it can be seen that the waves in the first surface have been transferred to the surface that has been ground. Thus while this technique produces a wafer of more uniform thickness, it does not eliminate the residual saw waves. Further, it is desirable to have a wafer back side finished with a randomized look, and wafer grinding can leave a grind pattern in the wafer surface. The grind pattern may comprise a generally concentric ring pattern. Removing the grind pattern cannot be satisfactorily accomplished using prior art etching processes, and such etching also degrades wafer geometry. If grind pattern removal is left to a polishing apparatus, such as a double side polisher, a substantial amount (e.g. about 10 microns) of stock removal is needed to remove the grind pattern.

Additional deficiencies in the current art, and improvements in the present invention, are described below and will be recognized by those skilled in the art.

### SUMMARY OF THE INVENTION

The present invention provides exemplary cluster tool systems and methods for processing wafers, such as semiconductor wafers, including systems and methods for grind polishing wafers to remove grind marks.

In one embodiment, a substrate processing system according to the present invention includes a first platen having a first platen surface adapted for mounting a substrate thereto, and a second platen having an annular ring coupled to a second platen surface. The annular ring includes a grinding surface, and the first platen is offset from the second platen to position a portion of the annular ring proximate a center of the substrate. The system further includes a controller coupled to the platens to facilitate operation thereof. In this manner, the substrate processing system is configured to use a grind polish process for the removal of grind patterns previously disposed in the substrate surface.

In one aspect, the substrate processing system includes a rotation device for rotating the first platen in a first direction and for rotating the second platen in a second direction opposite the first direction. In another aspect, a vacuum system is coupled to the first platen for creating a vacuum to hold the substrate thereto during rotation of the first platen and during grinding operations.

In one aspect, the annular ring has an outer diameter that is between about ten (10) inches and about twelve (12) inches, and an inner diameter that is between about eight (8) inches and about ten (10) inches. In a similar aspect, the annular ring has an inner radius and an outer radius, with the difference between the two radii being between about 0.5 inches and about 2.5 inches.

In a particular aspect, the grinding surface includes a felt pad. In another aspect, the grinding surface has a plurality of spaced apart abrasive pads, which in one embodiment further include a plurality of space apart slurry ports between at least some of the abrasive pads. Preferably, the slurry ports are coupled to a slurry source for delivering slurry to the substrate during grinding operations. The ports also may deliver other fluids, including deionized water, to the substrate.

In one embodiment of the present invention, a grind cluster tool for processing a substrate has a first grinder for grinding a substrate surface, such as during a process to decrease or remove thickness variations in the substrate. The first grinder leaves a grind pattern in the substrate surface. The cluster tool further includes a second grinder for grinding the substrate surface in a manner which removes the grind pattern from the substrate surface. The first and second grinders are within a clean room environment.

In one aspect, the clean room environment further includes a cleaner, such as an etchant bath or a spray-on liquid dispenser, for cleaning the substrate. In a particular embodiment, the second grinder includes a ring of abrasive material positioned to pass generally through a center of the substrate when the ring is rotated. The cluster tool includes a first rotation device for rotating the ring so that the abrasive material contacts the substrate surface, and a second rotation device for rotating the substrate.

The present invention further provides exemplary wafer processing methods. In one embodiment, a method of grinding a substrate includes providing first and second platens. The second platen has an annular ring coupled thereto, with the annular ring having an abrasive surface. A substrate having a grind pattern in a first substrate surface is mounted to the first platen. The method includes rotating the first platen to rotate the substrate, rotating the second platen to rotate the annular ring, and positioning the platens such that a portion of the abrasive surface contacts the first substrate surface. At least a portion of the platen rotation and positioning occurs simultaneously to remove the grind pattern from the first substrate surface.

In one aspect, the abrasive surface passes generally through a center of the first substrate surface when the first and second platens are rotated. In another aspect, the second platen is rotated at between about 500 RPM and about 4,000 RPM. In one aspect, the second platen has a plurality of slurry ports to deliver slurry to the substrate. In a particular aspect, the slurry has a pH between about 8.5 and about 13, and in one aspect is delivered to the first substrate surface at a rate between about 150 milliliters (ml) and about 250 ml per minute.

In still another aspect, the platen rotation and positioning are adapted to remove substrate material from the first substrate surface at a rate that is between about one (1) to about three (3) microns per minute. Preferably, the grind polishing occurs for a time sufficient to remove the grind pattern from the first substrate surface.

Other objects, features and advantages of the present invention will become more fully apparent from the following detailed description, the appended claims and the accompanying drawings.

### BRIEF DESCRIPTION OF THE DRAWINGS

FIG. 1 depicts a prior art method for processing a silicon wafer;

FIG. 2 is a simplified flow diagram of a wafer processing method according to the present invention;

FIGS. 3A-C depict grind damage cluster tools according to the present invention;

FIG. 4 depicts an edge profile/polish cluster tool according to the present invention;

FIGS. 5A and 5B depict double side polish cluster tools according to the present invention;

FIG. 6 depicts a finish polish cluster tool according to the present invention;

FIG. 7A depicts a simplified schematic view of a grind polisher according to the present invention; and

FIGS. 7B and 7C depict two alternative annular rings for use with the grind polisher of FIG. 7A.

### DESCRIPTION OF THE SPECIFIC EMBODIMENTS

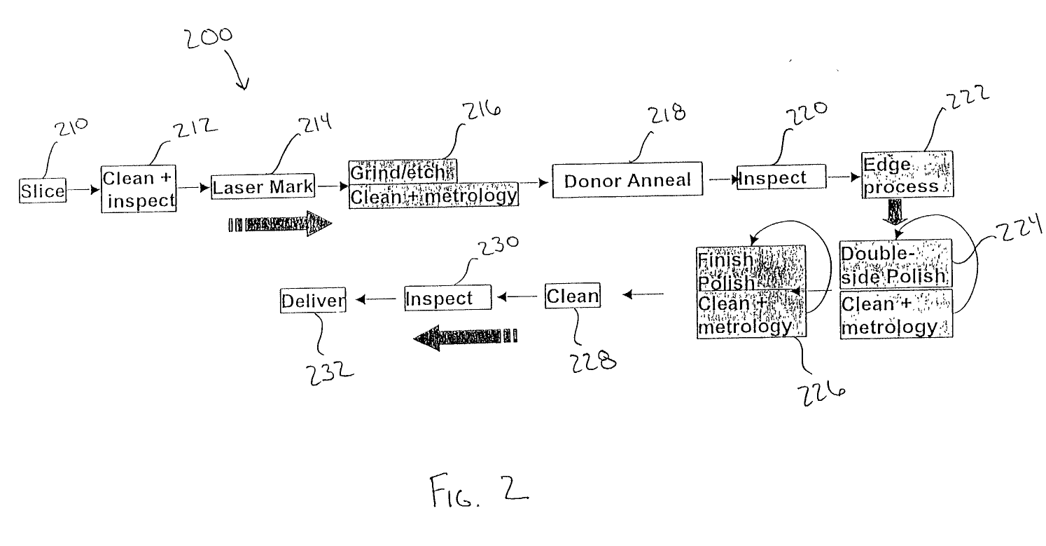

FIG. 2 depicts an exemplary method 200 of the present invention. Method 200 includes a slice process 210, using a wire saw, inner diameter saw or the like, to create a generally disc-shaped wafer or substrate. In one embodiment, the wafer is a silicon wafer. Alternatively, the wafer may comprise polysilicon, germanium, glass, quartz, or other materials. Further, the wafer may have an initial diameter of about 200 mm, about 300 mm, or other sizes, including diameters larger than 300 mm.

The wafer is cleaned and inspected (Step 212) and then may, or may not, be laser-marked (Step 214). Laser marking involves creating an alphanumeric identification mark on the wafer. The ID mark may identify the wafer manufacturer, flatness, conductivity type, wafer number and the like. The laser marking preferably is performed to a sufficient depth so that the ID mark remains even after portions of the wafer have been removed by subsequent process steps such as grinding, etching, polishing, and the like.

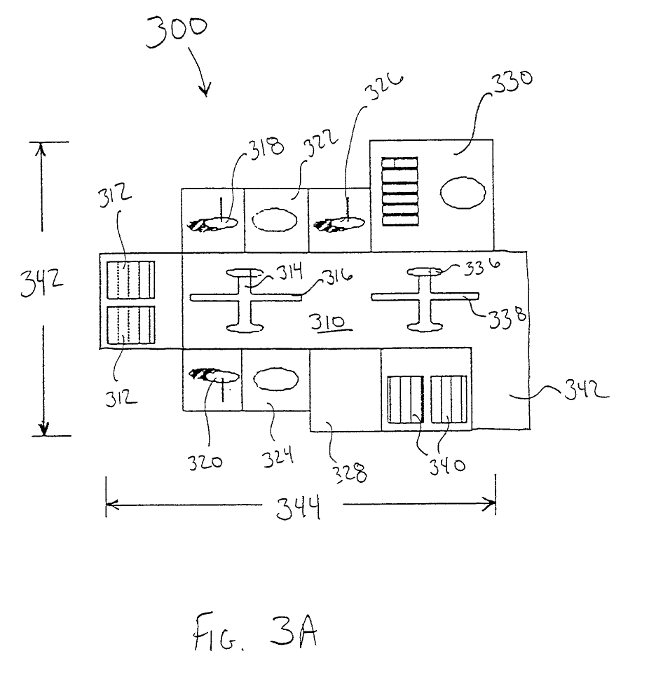

Thereafter, the wafer is processed through a first module (Step 216), with details of embodiments of the first module described below in conjunction with FIGS. 3A-3C. First module processing (Step 216) includes a grinding process, an etching process, a cleaning process and metrology testing of the wafer. In this module, the use of a grinding process in lieu of lapping helps to remove wafer bow and warpage. The grinding process of the present invention also is beneficial in removing wafer surface waves caused by the wafer slicing in Step 210. Benefits of grinding in lieu of lapping include reduced kerf loss, better thickness tolerance, improved wafer shape for polishing and better laser mark dot depth tolerance, and reduced damage, among others.

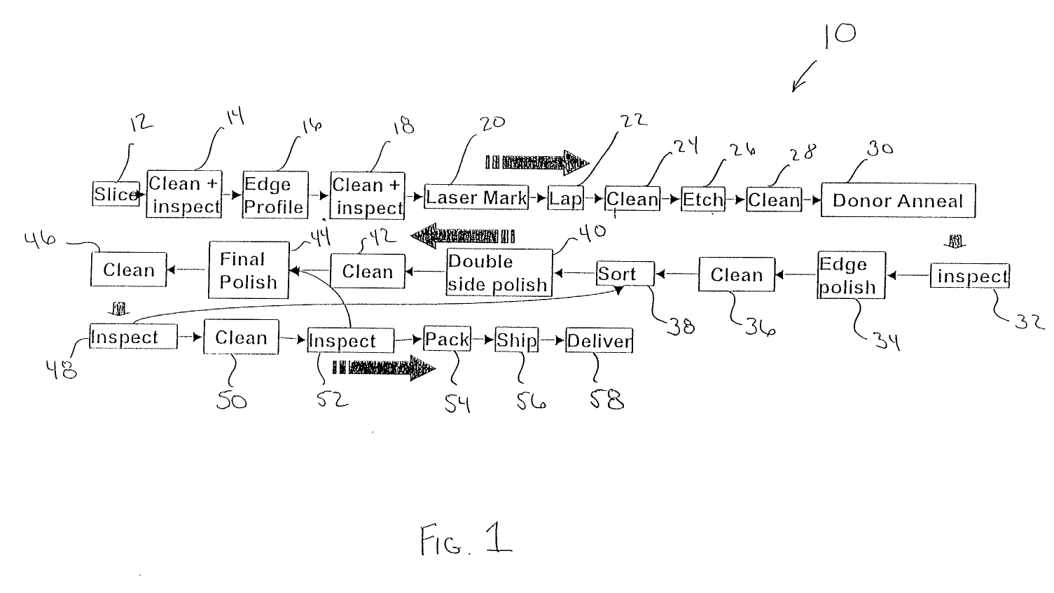

The etching process within the first module is a more benign process than the prior art etch step described in conjunction with FIG. 1. For example, typical prior art etching (Step 26 in FIG. 1) may involve the bulk removal of forty (40) or more microns of wafer thickness. In contrast, the etch process of the present invention preferably removes ten (10) microns or less from the wafer thickness. In one embodiment, the first module etch process removes between about two (2) microns to about five (5) microns of wafer material per side, or a total of about four (4) to about ten (10) microns. In another embodiment, the first module etch process removes between about three (3) microns and about four (4) microns of wafer material per side for a total of about six (6) to about (8) microns.

After first module processing, the wafer is subjected to a donor anneal (Step 218) and thereafter inspected (Step 220). The donor anneal removes unstable oxygen impurities within the wafer. As a result, the original wafer resistivity may be fixed. In an alternative embodiment, donor anneal is not performed.

The wafer then is processed through a second module (Step 222) in which an edge process is performed. The edge process includes both an edge profile and an edge polish procedure. Edge profiling may include removing chips from the wafer edge, controlling the diameter of the wafer and/or the creation of a beveled edge. Edge profiling also may involve notching the wafer to create primary and secondary flat edges. The flats facilitate wafer alignment in subsequent processing steps and/or provide desired wafer information (e.g., conductivity type). In one embodiment, one or both flats are formed near the ID mark previously created in the wafer surface. One advantage of the present invention involves performing the edge profiling after wafer grinding. In this manner, chips or other defects to the wafer edge, which may arise during grinding or lapping, are more likely to be removed. Prior art edge profiling occurs before lapping, and edge polishing subsequent to the lapping step may not sufficiently remove edge defects.

The wafer is then processed through a third module (Step 224). A third module process includes a double side polish, a cleaning process and wafer metrology. Wafer polishing is designed to remove stress within the wafer and smooth any remaining roughness. The polishing also helps eliminate haze and light point defects (LPD) within the wafer, and produces a flatter, smoother finish wafer. As shown by the arrow in FIG. 2, wafer metrology may be used to adjust the double side polishing process within the third module. In other words, wafer metrology may be feed back to the double side polisher and used to adjust the DSP device in the event the processed wafer needs to have different or improved characteristics, such as flatness, or to further polish out scratches.

Thereafter, the wafer is subjected to a finish polish, a cleaning process and metrology testing, all within a fourth process module (226). The wafer is cleaned (Step 228), inspected (Step 230) and delivered (Step 232).

The reduced number of clean and inspection steps, particularly near the end of the process flow, are due in part to the exemplary metrology processing of the wafer during prior process steps. Wafer metrology testing may test a number of wafer characteristics, including wafer flatness, haze, LPD, scratches and the like. Wafer flatness may be determined by a number of measuring methods known to those skilled in the art. For example, “taper” is a measurement of the lack of parallelism between the unpolished back surface and a selected focal plane of the wafer. Site Total Indicated Reading (STIR) is the difference between the highest point above the selected focal plane and the lowest point below the focal plane for a selected portion (e.g., 1 square cm) of the wafer, and is always a positive number. Site Focal Plane Deviation (SFPD) is the highest point above, or the lowest point below, the chosen focal plane for a selected portion (e.g., 1 square cm) of the wafer and may be a positive or negative number. Total thickness variation (TTV) is the difference between the highest and lowest elevation of the polished front surface of the wafer.

Further, metrology information, in one embodiment, is fed back and used to modify process parameters. For example, in one embodiment metrology testing in the first module occurs after wafer grinding and may be used to modify the grinding process for subsequent wafers. In one embodiment, wafers are processed through the first module in series. More specifically, each station within the first module processes a single wafer at a time. In this manner, metrology information may be fed back to improve the grinding or other process after only about one (1) to five (5) wafers have been processed. As a result, a potential problem can be corrected before a larger number of wafers have been processed through the problem area, thus lowering costs.

Further, the present invention produces standard process times for each wafer. More specifically, each wafer is subjected to approximately the same duration of grinding, cleaning, etching, etc. The delay between each process also is the same or nearly the same for each wafer. As a result, it is easy to troubleshoot within the present invention methods and systems.

In contrast, prior art methods typically uses a batch process mode for a number of process steps. For example, a batch containing a large number of wafers (say, twenty (20)) may be lapped one to a few at a time (say, one (1) to four (4) at a time). After all twenty have been lapped, the batch of twenty wafers then are cleaned together as a group (Step 24), and etched together as a group (Step 26). As a result, the wafers that were lapped first sit around for a longer period of time prior to cleaning than do the wafers lapped last. This varying delay effects wafer quality, due in part to the formation of a greater amount of haze, light point defects, and other time-dependent wafer defects. One negative outcome of irregular process times is the resultant difficulty in locating potential problems within the process system.

As with the first module, metrology information may be fed back within the second, third and fourth modules. For example, metrology information may be fed back to the double side polisher or finish polisher to adjust those processes to produce improved results. Additionally, in one embodiment, metrology information is fed back within the third and/or fourth module in real time. As a result, process steps such as the double side polishing can be modified during processing of the same wafer on which metrology testing has occurred.

With reference to FIGS. 3-6, additional details on process modules according to the present invention will be provided. It will be appreciated by those skilled in the art that the process modules described in FIGS. 3-6 are embodiments of the present invention, from which a large number of variations for each module exist within the scope of the present invention. Further, additional process steps may be removed or added, and process steps may be rearranged within the scope of the present invention.

FIG. 3A depicts a grind damage cluster module described as first module 216 in conjunction with FIG. 2. First module 300 defines a clean room environment 310 in which a series of process steps are carried out. Wafers that have been processed through Step 214 (FIG. 2) are received in first module 300 via a portal, such as a front opening unified pod (FOUP) 312. First module 300 is shown with two FOUPs 312, although a larger or smaller number of FOUPs/portals may be used. FOUPs 312 are adapted to hold a number of wafers so that the frequency of ingress into the clean room environment 310 may be minimized. A transfer device 314, schematically depicted as a robot, operates to remove a wafer from FOUPs 312 and place the wafer on a grinder 318. If needed, transfer device 314 travels down a track 316 to properly align itself, and hence the wafer, in front of grinder 318. Grinder 318 operates to grind a first side of the wafer.

The wafer may be held down on grinder 318 by way of a vacuum chuck, and other methods. Once grinder 318 has ground the first side of the wafer, the wafer is cleaned in cleaner 322 and the transfer device 314 transfers the wafer back to grinder 318 for grinding the converse side of the wafer. In one embodiment, wafer grinding of both wafer sides removes about forty (40) microns to about seventy (70) microns of wafer thickness. After the second wafer side is ground, the wafer is again cleaned in cleaner 322. In one embodiment, cleaning steps occur on grinder 318 subsequent to grinding thereon. In one embodiment, cleaning and drying are accomplished by spraying a cleaning solution on the wafer held by or near the edges and spun.

In another embodiment, at least one side of the wafer is subjected to two sequential grinding steps on grinder 318. The two grinding processes preferably include a coarse grind followed by a fine grind. Grinder 318 may include, for example, two different grinding platens or pads with different grit patterns or surface roughness. In one embodiment, the wafer is cleaned on grinder 318 between the two grinding steps to the same wafer side. Alternatively, cleaning may occur after both grinding steps to the same wafer side.

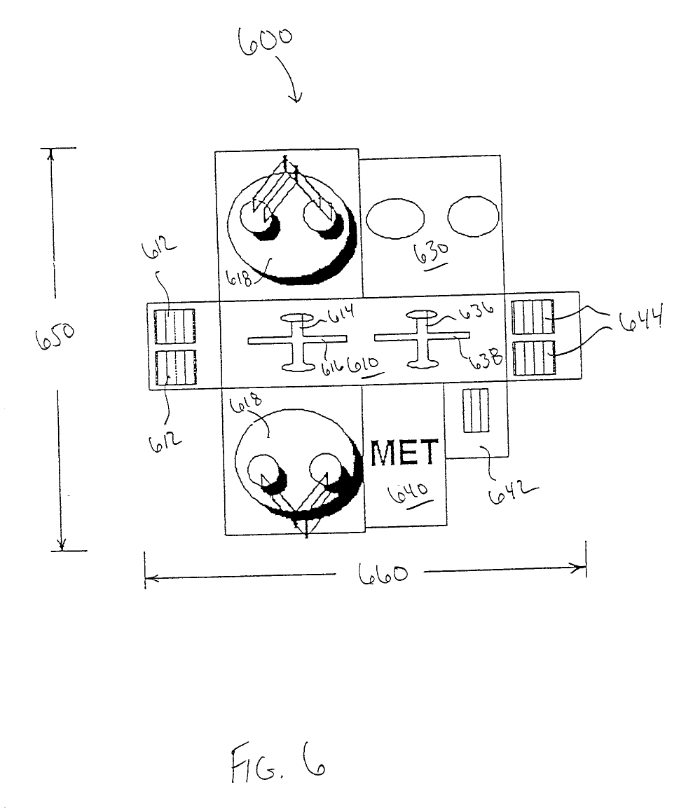

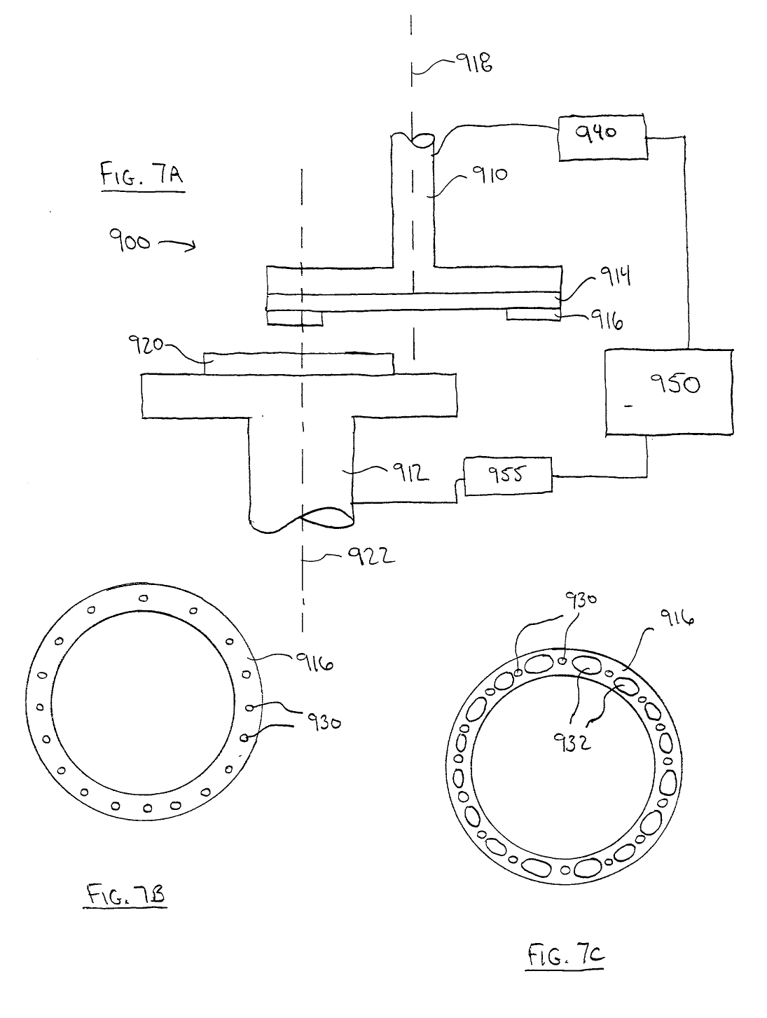

In some embodiments, transfer device 314 transfers the wafer from cleaner 322 to a backside polisher 326. For example, this process flow may occur for 200 mm wafers. In this embodiment, the back side is polished and not ground, or both ground and polished. In one embodiment, backside polisher 326 is a backside grinder for removing grind patterns from the wafer surface. Additional details on such an embodiment are discussed in conjunction with FIGS. 7A-7C herein.

As shown in FIG. 3A, a second grinder 320 and a second cleaner 324 are provided within module 300. In this manner, two wafers may be simultaneously processed therethrough. Since both grinders 318, 320 have a corresponding cleaner 322, 324, wafer processing times are consistent even if two wafers are being ground simultaneously on grinders 318, 320. In one embodiment, grinders 318 and 320 are used to grind opposite sides of the same wafer. In this case, one side of the wafer is ground on grinder 318 and the other side of the same wafer is ground on grinder 320. As with grinder 318, wafers may be ground on grinder 320 and then cleaned on grinder 320 before removal, or cleaned in cleaner 324.

Once the wafers have been ground, a second transfer device 336, again a robot in one embodiment, operates to transfer the wafer to an etcher 330. Etcher 330 operates to remove material from the wafer, preferably a portion on both primary sides of the wafer. The etching process is designed to remove stresses within the silicon crystal caused by the grinding process. Such an operation, in one embodiment, removes ten (10) microns or less of total wafer thickness. In this manner, etcher 330 operates to remove less wafer material than in prior art etch processes. Further, the present invention requires less etchant solution, and hence poses fewer environmental problems related to disposal of the acids or other etchants.

Wafer metrology is then tested at a metrology station 328. In one embodiment wafer metrology is tested subsequent to grinding on grinder 318, and prior to the etching within etcher 330. Alternatively, wafer metrology is tested subsequent to etching in etcher 330. In still another embodiment, wafer metrology is tested both prior to and subsequent to the etching process. Evaluation of wafer metrology involves the testing of wafer flatness and other wafer characteristics to ensure the wafer conforms to the desired specifications. If the wafer does not meet specifications, the wafer is placed in a recycle area 342, which in one embodiment comprises a FOUP 342 (not shown in FIG. 3A). Wafers with acceptable specifications are placed in an out portal or FOUP 340 for removal from first module 300.

As shown and described in conjunction with FIG. 3A, first module 300 provides an enclosed clean room environment in which a series of process steps are performed. Wafers are processed in series through first module 300. Hence, each wafer has generally uniform or uniform process time through the module as well as generally uniform or uniform delay times between process steps. Further, by immediately cleaning and etching the wafer after grinding, the formation of haze and light point defects (LPD) within the wafer are reduced. Such a module configuration is an improvement over the prior art in which wafers are typically processed during the lapping step in batch mode. As a result, some wafers will wait longer before the cleaning or etching steps than others within the same batch. As a result, haze and other wafer defects vary from wafer to wafer, even between wafers within the same batch. Such a shortcoming of the prior art can make it difficult if not impossible to isolate problems within the wafer process flow in the event defective wafers are discovered.

An additional benefit of first module 300 is its compact size. In one embodiment, module 300 has a width 342 that is about 9 feet 3 inches and a length 344 that is about 12 feet 6 inches. In another embodiment, first module 300 has a footprint ranging between about ninety (90) square feet (sqft) and about one hundred and fifty (150) square feet. It will be appreciated by those skilled in the art that the width and length, and hence the footprint of first module 300, may vary within the scope of the present invention. For example, additional grinders 318, 320 may be added within first module 300 to increase the footprint of module 300. In one embodiment, first module 300 is adapted to process about thirty (30) wafers per hour. In another embodiment, first module 300 is adapted to process between about twenty-nine (29) and about thirty-three (33) 300 mm wafers per hour.

FIG. 3B depicts an alternative embodiment of a grind damage cluster module according to the present invention. Again, the grind damage cluster module 350 may correspond to first module 216 described in conjunction with FIG. 2. Module 350 includes many of the same components as the embodiment depicted in FIG. 3A, and like reference numerals are used to identify like components. Module 350 receives wafers or substrates to be processed at portal 312, identified as a send FOUP 312 in FIG. 3B. Wafers are transferred by transfer device 314, shown as wet robot 314, to a preprocessing station 354. In one embodiment, transfer device 314 travels on a track, groove, raised member or other mechanism which allows transfer device 314 to reach several process stations within module 350.

At preprocessing station 354, a coating is applied to one side of the wafer. In one embodiment, a polymer coating is spun on the wafer to provide exemplary coverage. This coating then is cured using ultraviolet (UV) light to provide a low shrink, rapid cured coating on one side of the wafer. In addition to UV curing, curing of the coating may be accomplished by heating and the like. In a particular embodiment, the coating is applied to a thickness between about five (5) microns and about thirty (30) microns.

Once cured, the coating provides a completely or substantially tack free, stress free surface on one side of the wafer. In one embodiment of the present invention, transfer device 314 transfers the wafer to grinder 318, placing the polymer-coated side down on the grinder 318 platen. In one embodiment, the platen is a porous ceramic chuck which uses a vacuum to hold the wafer in place during grinding. The waves created during wafer slicing are absorbed by the coating and not reflected to the front side of the wafer when held down during the grinding process. After the first wafer side is ground on grinder 318, the wafer is flipped over and the second side is ground. As described in conjunction with FIG. 3A, an in situ clean of the wafer may occur before turning the wafer, or the wafer may be cleaned subsequent to grinding of both sides. Again, the second side grinding may occur on grinder 318 or grinder 320. Grinding of the second side removes the cured polymer, and a portion of the second wafer surface resulting in a generally smooth wafer on both sides, with little to no residual surface waves. Additional details on exemplary grinding methods are discussed in U.S. patent application Ser. No. ______ (Attorney Docket No. 20468-001010), filed contemporaneously herewith, the complete disclosure of which is incorporated herein by reference.

After grinding on grinder 318 and/or 320, the wafer is transferred to a combined etch/clean station 352 for wafer etch. Again, wafer etching in station 352 removes a smaller amount of wafer material, and hence requires a smaller amount of etchant solutions, than is typically required by prior art processes.

Processing continues through module 350 ostensibly as described in FIG. 3A. The wafer metrology is tested at metrology station 328. Wafers having desired characteristics are transferred by transfer device 336, shown as a dry robot, to out portals 340, identified as receive FOUPS 340 in FIG. 3B. Wafers having some shortcoming or undesirable parameter are placed in a recycle area 342, shown as a buffer FOUP 342, for appropriate disposal.

In one embodiment, module 350 has a width 342 at its widest point of about one hundred and fourteen (114) inches, and a length at its longest point of about one hundred and forty-five inches (145), with a total footprint of about one hundred and fourteen square feet (114 sq. ft. ). As will be appreciated by those skilled in the art, the dimensions and footprint of module 350 may vary within the scope of the present invention.

Still another embodiment of a grind damage cluster module according to the present invention is shown in FIG. 3C. FIG. 3C depicts a first module 360 having similar stations and components as module 350 described in FIG. 3B. However, module 350 is a flow through module, with wafers being received at one end or side of module 350 and exiting an opposite end or side of module 350. Module 360 has FOUPS 312, 342 and 340 grouped together. Such a configuration provides a single entry point into module 360, and hence into clean room environment 310. Transfer devices 314 and 336 again facilitate the movement of wafers from station to station within module 360. As shown in FIGS. 3B and 3C, transfer device 314 travels on mechanism 316, as discussed in conjunction with FIG. 3B. Transfer device 336 operates from a generally fixed position with arms or platens extending therefrom to translate the wafer to the desired processing station. Module 360 further includes station 354 for application of a wafer coating, such as the UV cured polymer coating described above.

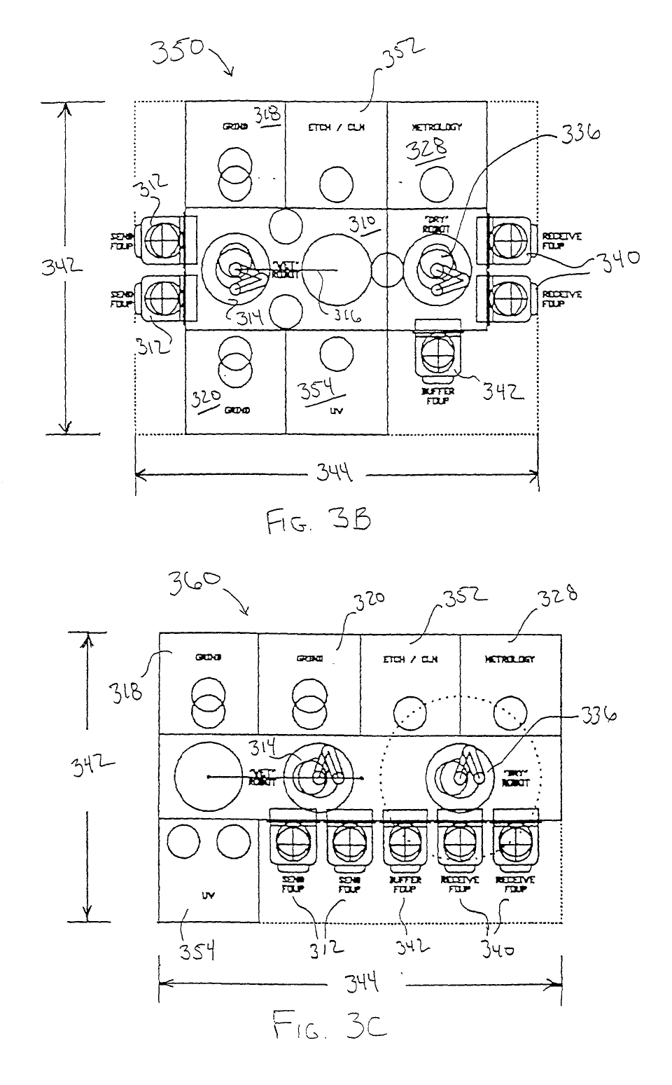

Turning now to FIG. 4, an exemplary second module comprising an edge profile and edge polishing module will be described. Second module 400 again includes a clean room environment 410 to facilitate clean operations. Second module 400 has a portal 412 for receiving wafers to be processed. Again, in one embodiment, portal 412 is one or more FOUPs. A robot or other transfer device 414 operates to take a wafer from portal 412 and transfer the wafer to an edge profiler/polisher 418. Edge profiler/polisher 418 may comprise one device, or two separate devices with the first device for profiling and the second device for polishing. Transfer device 414 may travel down a track 416 to permit proper placement of the wafer in the edge profiler/polisher 418.

The edge of the wafer is profiled and polished as described in conjunction with FIG. 2. In one embodiment, edge profiling removes about ten (10) microns to about fifty (50) microns of material from the diameter of the wafer, with a resultant diameter tolerance of about +/−0.5 μ. After edge profiling and polishing, a transfer device 420 operates to transfer the wafer to a cleaner 430. Again, transfer device 420 may travel on a track 422 to place the wafer in cleaner 430. Cleaner 430 may comprise a mixture of dilute ammonia, peroxide, and water, or an ammonia peroxide solution and soap, followed by an aqueous clean, and the like.

Subsequent to cleaning in cleaner 430, the wafer is transferred to a metrology station 432 at which wafer metrology is examined. An out-portal 434 is positioned to receive wafers having successfully completed processing through second module 400. In one embodiment, portal 434 is a FOUP which collects wafers meeting desired specifications. Again, rejected wafers are set aside in a separate area or FOUP.

Second module 400 has a compact configuration similar to first module. In one embodiment, second module 400 has a width 450 of about 7 feet 6 inches and a length 460 of about 22 feet 11 inches. In another embodiment, second module 400 has a footprint ranging between about ninety (90) square feet (sqft) and about one hundred and fifty (150) square feet. The module 400 shown in FIG. 4 may be used to carry out process step 222 depicted in FIG. 2. In one embodiment, second module 400 processes about thirty (30) wafers per hour. In another embodiment, second module 400 is adapted to process between about twenty-nine (29) and about thirty-three (33) 300 mm wafers per hour. In still another embodiment, second module 400 processing occurs prior to first module 300 processing. In this manner, edge profile and/or edge polish procedures occur before wafer grinding.

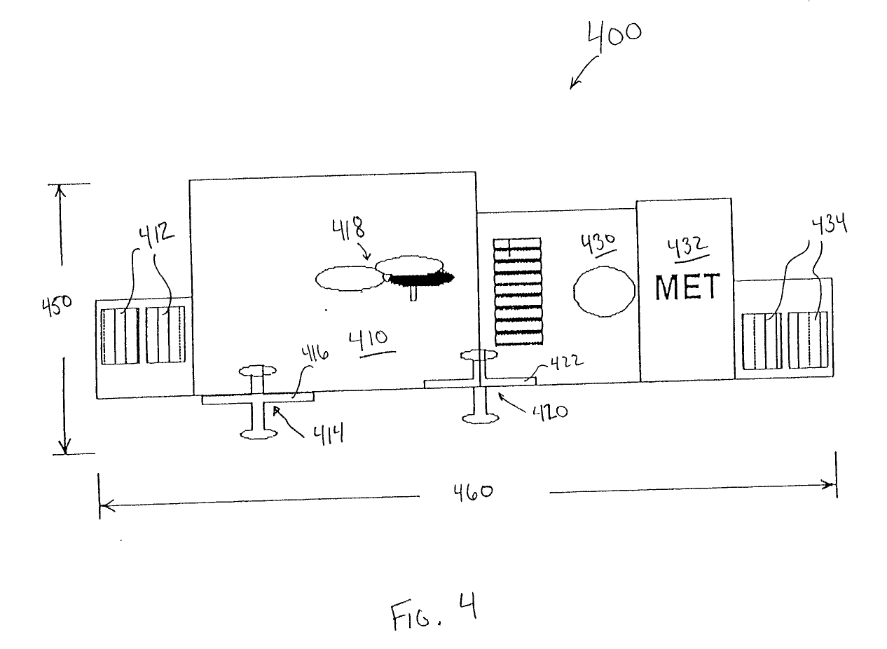

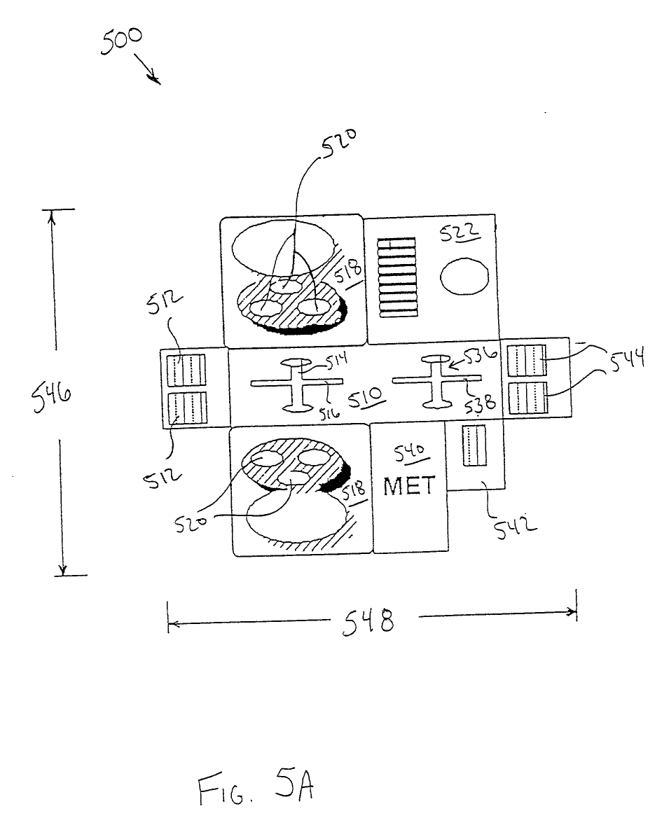

FIG. 5A depicts a third module 500 comprising a double side polisher for use in process step 224 shown in FIG. 2. Module 500 again includes an in-portal 512 which may be one or more FOUPs in one embodiment. Wafers are received in portal 512 and transferred within a clean room environment 510 by a transfer device 514. Transfer device 514, which in one embodiment is a robot, may travel along a track 516 to deliver the wafer to one or more double side polishers (DSP) 518.

As shown in FIG. 5A, double side polisher 518 accommodates three wafers 520 within each polisher. It will be appreciated by those skilled in the art that a greater or fewer number of wafers may be simultaneously polished within DSP 518. Prior art double side polishing (DSP) typically polishes a batch of ten or more wafers at a time in a double side polisher. The polisher initially only contacts the two or three thickest wafers due to their increased height within the DSP machine. Only after the upper layers of the thickest wafers are removed by polishing, are additional wafers polished within the batch. As a result, the batch mode polishing takes longer, and uses more polishing fluids and deionized water than in the present invention.

Hence in one preferred embodiment of the present invention, three wafers are polished simultaneously. Subsequent to polishing on polisher 518, the wafers are transferred via a transfer device 536, traveling on track 538 to a buffer station 522. Thereafter, the wafers are buffed, cleaned and dried. Either prior to or after processing through station 522, or both, wafers are tested at a metrology station 540. For wafers meeting desired specifications, transfer device 536 transfers those wafers to an out-portal 544, again, one or more FOUPs in one embodiment. Wafers which do not meet specifications are placed in a reject FOUP 542.

As with prior modules, the third module 500 has a compact footprint. In one embodiment, module 500 has a width 546 that is about 13 feet 11 inches and a length 548 that is about 15 feet 11 inches. In another embodiment, third module 500 has a footprint ranging between about one hundred (100) square feet (sqft) and about one hundred and eighty (180) square feet. Third module 500 may have a different footprint within the scope of the present invention.

In one embodiment, DSP 518 removes about twelve (12) microns of wafer thickness from both sides combined, at a rate of about 1.25 to 2.0 microns per minute. DSP 518 operates on a twelve (12) minute cycle time per load. Hence, in one embodiment, two DSPs 518 process about thirty (30) wafers per hour. In another embodiment, third module 500 is adapted to process between about twenty-nine (29) and about thirty-three (33) 300 mm wafers per hour. It will be appreciated by those skilled in the art that DSP 518 process times, third module 500 throughput, and other parameters may vary within the scope of the present invention. For example, additional DSPs 518 may be added to increase module 500 throughput. In one embodiment, wafer metrology tested at metrology station 540 is fed back to DSPs 518 to adjust DSP 518 operation as needed to produce desired wafer metrology.

FIG. 5B depicts an alternative embodiment of a third module according to the present invention. As shown in FIG. 5B, third module 550 comprises a double side polisher for use in process step 224 shown in FIG. 2, as well as several other components shown in FIG. 5A. As a result, like components are identified with like reference numerals. Module 550 includes a clean/dry station 552 for wafer cleaning and drying subsequent to wafer polishing in polisher 518. Transfer devices 514 and 536, shown as a wet robot and a dry robot, respectively, operate to transfer wafers within module 550. In one embodiment, transfer device 514 travels on a track, groove, raised feature or the like to reach several processing stations and portals 512, while transfer device 536 operates from a fixed base.

While module 500 in FIG. 5A is a flow through module, with wafers received by module 500 at one side and exiting from an opposite side, module 550 in FIG. 5B groups portals 512 and 544. Again, such a grouping of in and out portals facilitates access to module 550 from a single point or side. In one embodiment, a buffer or reject FOUPS (not shown) also is grouped with portals 512 and 544. Alternatively, one or more of portals 512 and 544 may operate as a reject FOUPS.

Third module 550, in one embodiment, has a compact footprint with a width 546 at the widest point of about one hundred and forty two (142) inches and a length at the longest point of about one hundred and fifty-five inches (155).

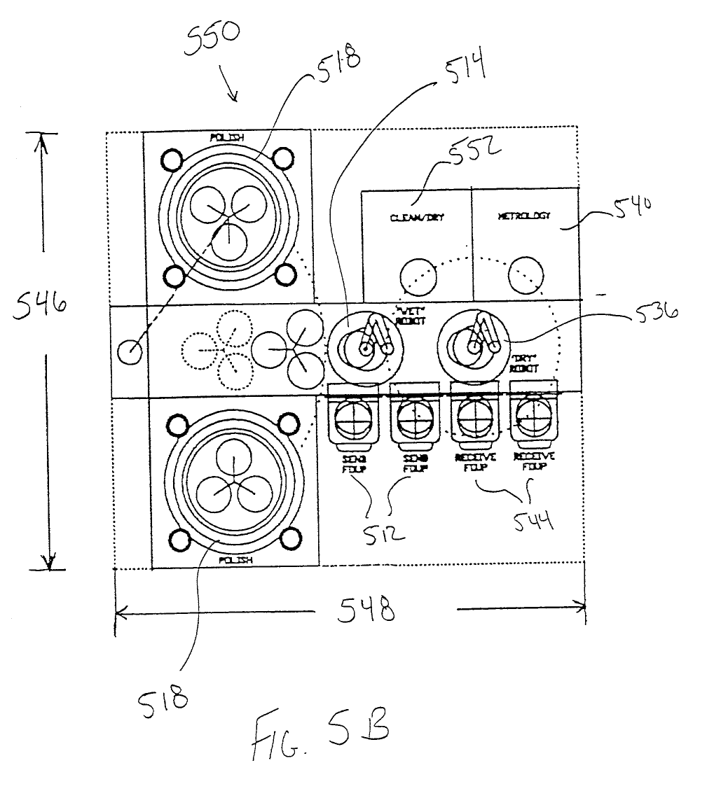

Turning now to FIG. 6, a fourth module 600, comprising a finish polish cluster, will be described. Fourth module 600 in one embodiment will be used for process step 226 shown in FIG. 2. As with the prior modules, fourth module 600 defines a clean room environment 610 which has ingress and egress through one or more portals or FOUPs. For example, an in-portal or FOUP 612 receives a plurality of wafers for finish polishing. Wafers are removed from FOUP 612 and transferred by a transfer device 614 along a track 616 to a finish polisher 618. While two finish polishers 618 are depicted in FIG. 6, a larger or smaller number of polishers 618 may be used within the scope of the present invention.

Wafers are finish polished for about five (5) to six (6) minutes within finish polisher 618 in an embodiment. Wafers that have undergone finish polishing are transferred to a single wafer cleaner 630 by a transfer device 636. Again, transfer device 636 in one embodiment comprises a robot that travels along a track 638. After wafer cleaning at cleaner station 630, wafer metrology is again tested at a metrology station 640. In one embodiment, metrology processing within fourth module 600 uses a feedback loop to provide data to finish polishers 618 as a result of wafer metrology testing. In one embodiment, the feedback loop is of sufficiently short duration to permit adjustments to the finish polisher process prior to the polishing of the next wafer after the wafer being tested. Wafers which do not meet specification are placed in a reject FOUP or portal 642 for proper disposal. Wafers meeting specifications will be placed in an out-portal or FOUP 644 for subsequent processing, packaging and shipping.

Fourth module 600, in one embodiment, has a width 650 of about 14 feet 0 inches and a length 660 of about 16 feet 0 inches. In another embodiment, fourth module 600 has a footprint ranging between about one hundred (100) square feet (sqft) and about one hundred and eighty (180) square feet. Again, as with all prior modules, the exact size may vary within the scope of the present invention. In one embodiment, fourth module 600 processes about thirty (30) wafers per hour. In another embodiment, fourth module 600 is adapted to process between about twenty-nine (29) and about thirty-three (33) 300 mm wafers per hour.

In one embodiment, the four modules 300, 400, 500 and 600, or their alternative embodiments, and ancillary equipment take up about 4,000 square feet or less of a production facility. This total footprint is much smaller than required for prior art equipment performing similar processes. As a result, apparatus, systems and methods of the present invention may be incorporated more readily in smaller facilities, or as part of a device fabrication facility in which circuit devices are formed. In this manner, the time and cost of packing and shipping, as well as unpacking and inspecting, are avoided. The costs of packing and shipping can, for example, save on the order of about two (2) percent or more of the total wafer processing costs. Additional details on exemplary in-fab wafer processing methods are discussed in U.S. patent application Ser. No. ______ (Attorney Docket No. 20468-000310), entitled “Cluster Tool Systems and Methods for In Fab Wafer Processing,” filed contemporaneously herewith, the complete disclosure of which is incorporated herein by reference.

Turning now to FIGS. 7A-7C, an exemplary grind polisher 900 according to the present invention will be described. Grind polisher 900 may be used as backside polisher 326 depicted in FIG. 3A. Alternatively, grind polisher 900 may be a stand alone device outside the cluster tool configuration shown in FIG. 3A. Grind polisher 900 includes a first platen 912 and a second platen 910. First platen 912 has a substrate or wafer 920 coupled thereto. In one embodiment, substrate 920 is coupled using a vacuum system 955 shown schematically in FIG. 7A. Vacuum system 955, in one embodiment, comprises a plurality of holes (not shown) in first platen 912 that are coupled to a pump, which creates a vacuum or down force to hold substrate 920 on platen 912. Other substrate retention systems also may be used within the scope of the present invention. Preferably, first platen 912 is adapted to rotate about an axis 922 using a rotation device (not shown). The rotation device may include a wide range of devices within the scope of the present invention, including gear and pulley systems as well as hydraulic or other devices.

Second platen 910 has a backing plate 914, which in one embodiment comprises aluminum, stainless steel, and the like. Backing plate 914 has an annular ring 916 coupled thereto. Annular ring 916 also may comprise aluminum, stainless steel, other metals and the like. In one embodiment, annular ring 916 and backing plate 914 comprise a ceramic. In another embodiment, annular ring 916 is coupled directly to second platen 910 without the use of backing plate 914. As best shown in FIG. 7B, in one embodiment annular ring 916 comprises a generally circular ring having an inner diameter and an outer diameter. In one embodiment, the inner diameter is between about eight (8) inches and about ten (10) inches, and the outer diameter is between about ten (10) inches and about twelve (12) inches. Similarly, in an embodiment, the inner radius of annular ring 916 is between about 0.5 and about 2.5 inches smaller than the outer radius of annular ring 916.

Preferably, annular ring 916 has an abrasive surface. The abrasive surface may comprise a felt, a diamond mesh, an externally activated abrasive cloth, and the like, including abrasive pads known to those skilled in the art. As shown in FIG. 7B, the abrasive surface of annular ring 916 has a plurality of ports 930 disposed therethrough. In one embodiment, ports 930 comprise slurry ports which are coupled to a slurry system. In this embodiment, ports 930 pass through the abrasive surface of annular ring 916, through backing plate 914, and through a portion of second platen 910, by which they are coupled to a slurry source (not shown). The ports 930 provide a mechanism for delivering a slurry to substrate 920. Alternatively, ports 930 deliver deionized water and other fluids as needed to substrate 920.

As shown in FIG. 7A, grind polisher 900 further includes a rotator 940 adapted to rotate second platen 910 about an axis 918. Rotator 940 is coupled to a controller 950 for controlling operation of rotator 940. In one embodiment, platens 910 and 912 are rotated in opposite directions (e.g., clockwise and counterclockwise). Controller 950 also is coupled to vacuum system 955, and may further be coupled to the rotation device for rotating first platen 912 (not shown) as previously described. In an alternative embodiment to that shown in FIG. 7B, FIG. 7C depicts annular 916 having a series of abrasive pads 932 disposed about annular ring 916. Ports 930 are positioned between at least some of pads 932, or between all pads 932 as shown in FIG. 7C. Again, ports 930 are adapted to deliver slurry, deionized water or other fluids to substrate 920.

In conjunction with FIGS. 7A-7C, operation of grind polisher 900 will now be described. Substrate 920 is transferred to first platen 912 and restrained using vacuum system 955. Platen 912 is then rotated to rotate substrate 920. Rotation of platen 912 may occur at a wide range of rotation speeds within the scope of the present invention. In a particular embodiment, platen 912 is rotated at about 100 RPM, although platen 912 rotation speeds may vary. An exposed surface 960 of substrate 920 has a residual grind pattern which results from grinding operations, such as that occurring in grinders 318, 320 shown in FIG. 3A. In one embodiment, surface 960 comprises a back surface of substrate 920, with the opposite or front surface intended to have a circuit device formed thereon.

As previously noted, it is desirable to remove the residual grind pattern in order to provide a randomized surface 960. Grind polisher 900 removes the grind pattern by rotating second platen 910 about axis 918 while the abrasive portion of annular ring 916 contacts surface 960. In one embodiment, second platen 910, and hence annular ring 916, is rotated at a rotation speed that is between about 500 revolutions per minute (RPM) and about 4,000 RPM. In alternative embodiments, second platen 910 is rotated between about 1,000 RPM and about 4,000 RPM, and between about 2,000 RPM and about 4,000 RPM. Contact between the abrasive surface of annular ring 916 and substrate surface 960 occurs at a sufficient down force to provide material removal rates of between about one (1) micron to about three (3) microns per minute. In addition, in one embodiment, the width of annular ring and rotation speeds provide an overlap of the material removal path in each cycle of the platen rotation. Compared to tradition polishing processes, which may remove several more microns of material per minute, the grind polishing of the present invention removes a small amount of stock material from surface 960.

In one embodiment, a slurry is delivered to substrate 920, such as by ports 930 in annular ring 916, during rotation of second platen 910. In one embodiment, the slurry is delivered to substrate 920 at a rate between about 150 milliliters (ml) to about 250 ml per minute. In one embodiment, the slurry has a pH ranging between about 8.5 and 13. In a particular embodiment, the slurry comprises Syton HT 50, and is delivered at a flow rate of about 200 ml per minute.

In a particular embodiment, grind polisher 900 is operated for about one (1) minute to remove about one (1) micron of material from substrate surface 960. According to apparatus and methods of the present invention, grind polishing of substrate 920 removes the visual grind pattern from surface 960. While masking the grind pattern on surface 960, the grind polishing may or may not remove all subsurface damage that may result from grinding surface 960 in grinder 318, 320. After grind polishing, a clean or etch process may, or may not, be performed. In one embodiment, surface 960 is cleaned using an etchant bath, a caustic bath, a spray on cleaner, or the like. Preferably, due at least in part to the grind polishing, the clean or etch is shorter in time than with the prior art methods, and may use a smaller amount of etchant materials.

As shown, preferably, the center of platens 910 and 912, and hence the axii of rotation 918, 922 are laterally offset from one another. In this manner, the annular ring abrasive surface passes generally through the center of substrate surface 960 during rotation of second platen 910. The configuration shown in FIGS. 7A, coupled with the rotation of both platens 910 and 912, results in exemplary grind polishing of the entire substrate surface 960.

Use of apparatus and methods of the present invention produce a substrate having the backside grind pattern masked or removed. Surface 960 is left with a randomized look, and with an Ra comparable to a polished surface. Further, substrate 920 geometry is not degraded by the present invention, as may otherwise occur with prior art etching after grinding.

The invention has now been described in detail for purposes of clarity and understanding. However, it will be appreciated that certain changes and modifications may be practiced within the scope of the appended claims. For example, the modules may have different layouts, dimensions and footprints than as described above. Additionally, transfer devices that have been described as traveling or fixed, may also be fixed or traveling, respectively.

What is claimed is:

1. A substrate processing system comprising:.
a first platen having a first platen surface adapted for mounting a substrate thereto;
a second platen having an annular ring coupled to a second platen surface, said annular ring comprising a grinding surface;
wherein said first platen is offset from said second platen to position a portion of said annular ring proximate a center of said substrate; and
a controller coupled to said first and second platens.

2. The substrate processing system as in claim 1 further comprising a rotation device for rotating said first platen in a first direction and for rotating said second platen in a second direction opposite said first direction.

3. The substrate processing system as in claim 1 further comprising a vacuum system coupled to said first platen for creating a vacuum to hold said substrate to said first platen surface.

4. The substrate processing system as in claim 1 wherein said annular ring comprises an outer diameter that is between about ten (10) inches and about twelve (12) inches, and an inner diameter that is between about eight (8) inches and about ten (10) inches.

5. The substrate processing system as in claim 1 wherein said annular ring has an inner radius and an outer radius, and wherein a difference between said inner radius and said outer radius is between about 0.5 inches and about 2.5 inches.

6. The substrate processing system as in claim 1 wherein said grinding surface comprises a felt pad.

7. The substrate processing system as in claim 1 wherein said grinding surface comprises a plurality of spaced apart abrasive pads.

8. The substrate processing system as in claim 7 wherein said annular ring further comprises a plurality of space apart slurry ports between at least some of said abrasive pads.

9. The substrate processing system as in claim 1 wherein said annular ring further comprises a plurality of spaced apart holes therethrough, said holes coupled to a slurry source for delivering slurry to said substrate.

10. A grind cluster tool for processing a substrate, said cluster tool comprising:
a first grinder for grinding a substrate surface, said first grinder leaving a grind pattern in said substrate surface; and
a second grinder for grinding said substrate surface, said second grinder for removing said grind pattern from said substrate surface;
wherein said first and second grinders are within a clean room environment.

11. The grind cluster tool as in claim 10 further comprising a cleaner for cleaning said substrate.

12. The grind cluster tool as in claim 10 wherein said second grinder comprises:
a ring of abrasive material positioned to pass generally through a center of said substrate when said ring is rotated;
a first rotation device for rotating said ring so that said abrasive material contacts said substrate surface; and
a second rotation device for rotating said substrate.

13. The grind cluster tool as in claim 10 wherein said second grinder comprises the substrate processing system as in claim 1.

14. A method of grinding a substrate, said method comprising:
providing first and second platens, said second platen having an annular ring coupled thereto, said annular ring having an abrasive surface;
mounting a substrate to said first platen, said substrate having a grind pattern in a first substrate surface;
rotating said first platen to rotate said substrate;
rotating said second platen to rotate said annular ring; and
positioning said platens such that a portion of said abrasive surface contacts said first substrate surface;
wherein at least a portion of said rotating said first platen, said rotating said second platen and said positioning occur simultaneously to remove said grind pattern from said first substrate surface.

15. The method of claim 14 wherein said positioning comprises positioning said platens so that said abrasive surface passes generally through a center of said first substrate surface during said rotating said first and second platens.

16. The method of claim 14 wherein said rotating said second platen comprises a rotation speed between about 500 RPM and about 4,000 RPM.

17. The method of claim 14 wherein said second platen further comprises a plurality of slurry ports for delivering slurry to said first substrate surface.

18. The method of claim 17 wherein said slurry has a pH between about 8.5 and about 13.

19. The method of claim 17 wherein said slurry is delivered to said first substrate surface at a rate between about 150 milliliters (ml) and about 250 ml per minute.

20. The method of claim 14 wherein said rotating and positioning are adapted to remove substrate material from said first substrate surface at a rate that is between about one (1) to about three (3) microns per minute.

21. The method of claim 14 wherein said rotating and positioning are performed for a time sufficient to remove said grind pattern from said first substrate surface.
